(19) United States
(12) Patent Application Publication
(10) Pub. No.: US 2025/0384905 A1
(43) Pub. Date: Dec. 18, 2025

(54) MEMORY DEVICE AND OPERATING METHOD THEREOF

(71) Applicant: Winbond Electronics Corp., Taichung City (TW)

(72) Inventors: Ching Hsun Li, Hsinchu (TW); Shih-Feng Huang, Hsinchu County (TW); Bin-Chi Chiou, Hsinchu County (TW)

(73) Assignee: Winbond Electronics Corp., Taichung City (TW)

(21) Appl. No.: 19/216,618

(22) Filed: May 22, 2025

(30) Foreign Application Priority Data
Jun. 18, 2024 (TW) 113122412

(51) Int. Cl. G11C 7/10; G11C 7/14

(52) U.S. Cl. CPC G11C 7/1039; G11C 7/1051; G11C 7/14

(57) ABSTRACT

A memory device including a voltage detecting circuit and an input-output buffer circuit is provided. The voltage detecting circuit receives a voltage signal and detects a level of the voltage signal. The input-output buffer circuit is disposed in the memory device, and coupled to the voltage detecting circuit. Based on the detecting result of the voltage detecting circuit, an operating voltage range of the input-output buffer circuit is set. The operating voltage range of the input-output buffer circuit corresponds to at least two different operating voltage ranges.

### CROSS-REFERENCE TO RELATED APPLICATION

This application claims the priority benefit of Taiwan application serial no. 113122412, filed on Jun. 18, 2024. The entirety of the above-mentioned patent application is hereby incorporated by reference herein and made a part of this specification.

### BACKGROUND

### Technical Field

The disclosure relates to a semiconductor device and an operating method thereof, and in particular to a memory device and an operating method thereof.

### Description of Related Art

Generally speaking, memory devices can usually only support a level of a voltage signal level of a single power input. If you want a memory device to support the level of the voltage signal of another power input at the same time, you can only design another memory device to support the level of the voltage signal of another power input. In this way, there may be two memory devices that have the same structure and function, and the only difference lies in the different levels of the voltage signal of the power input. However, such a solution increases the complexity for manufacturers in production, inventory, material preparation, cost control, and application design.

### SUMMARY

The disclosure provides a memory device and an operating method thereof, which can support levels of voltage signals of different power inputs.

The memory device according to the embodiment of the disclosure includes a voltage detecting circuit and an input-output buffer circuit. The voltage detecting circuit is configured to receive a voltage signal and detect a level of the voltage signal. The input-output buffer circuit is disposed in the memory device, and coupled to the voltage detecting circuit. Based on a detecting result of the voltage detecting circuit, an operating voltage range of the input-output buffer circuit is set. The operating voltage range of the input-output buffer circuit corresponds to at least two different operating voltage ranges.

The operating method of the memory device according to the embodiment of the disclosure includes: receiving the voltage signal and detecting the level of the voltage signal; and setting the operating voltage range of the input-output buffer circuit in the memory device according to the detecting result. The operating voltage range of the input-output buffer circuit corresponds to at least two different operating voltage ranges.

To make the aforementioned more comprehensible, several embodiments accompanied with drawings are described in detail as follows.

### BRIEF DESCRIPTION OF THE DRAWINGS

FIG. 1 is a schematic diagram illustrating an internal composition of a memory device according to an embodiment of the disclosure.

FIG. 2 is a schematic diagram of an internal structure of a voltage detecting circuit of the embodiment of FIG. 1

FIG. 3 is a flowchart illustrating an operating method of a memory device according to an embodiment of the disclosure.

### DESCRIPTION OF THE EMBODIMENTS

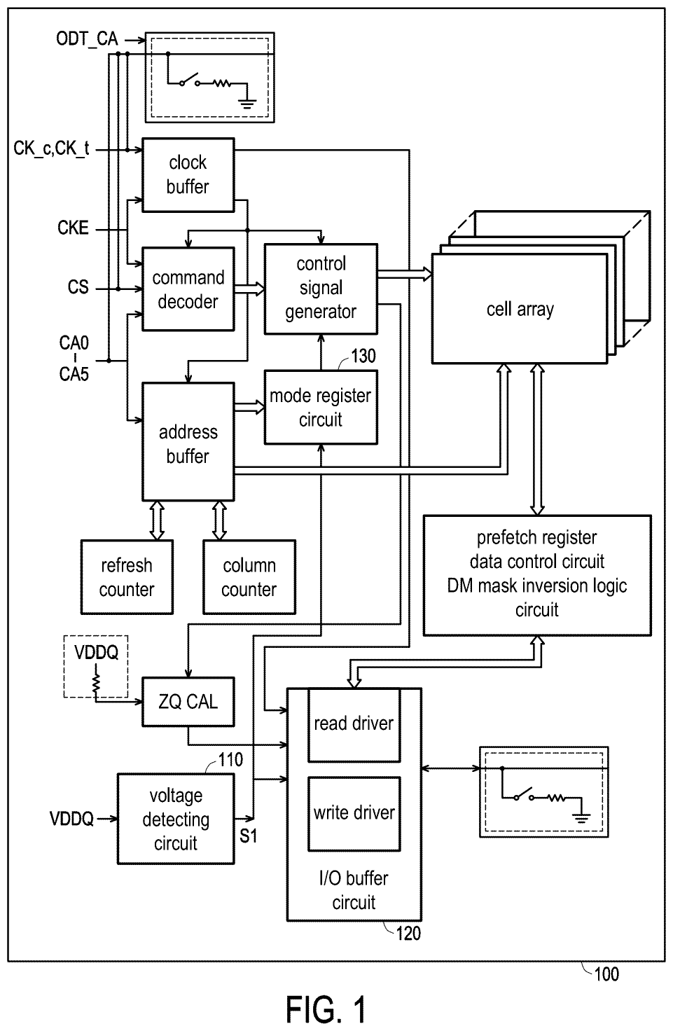

Referring to FIG. 1, a memory device 100 includes a voltage detecting circuit 110, an input-output (I/O) buffer circuit 120, and a mode register circuit 130. The I/O buffer circuit 120 and the mode register circuit 130 are coupled to the voltage detecting circuit 110. The internal circuit structure of the memory device 100 in FIG. 1 is used for exemplary illustration and is in no way limiting.

Specifically, the voltage detecting circuit 110 is used to receive a voltage signal VDDQ and detect a level of the voltage signal VDDQ. Then, based on a detecting result of the voltage detecting circuit 110, an operating voltage range of the I/O buffer circuit 120 is set. Alternatively, a mode setting of a mode register circuit 130 may also be adjusted according to the detecting result of the voltage detecting circuit 110. In addition, based on the detecting result of the voltage detecting circuit 110, the operating voltage range of the I/O buffer circuit 120 may also be set and the mode setting of the mode register circuit 130 may be adjusted. The operating voltage range of the I/O buffer circuit 120 may correspond to at least two different operating voltage ranges, and the mode register circuit 130 may store at least two different mode settings.

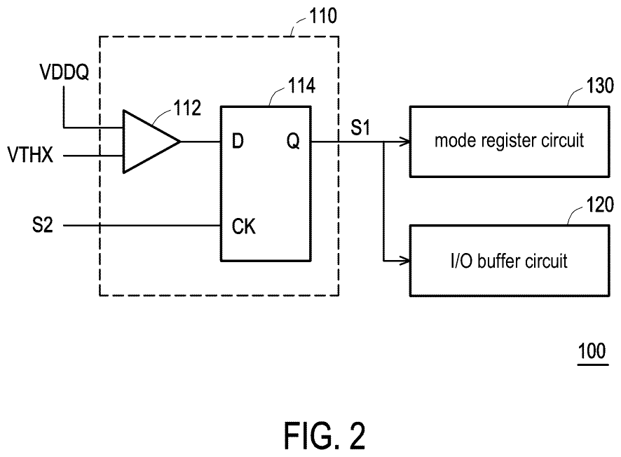

Referring to FIG. 2, the voltage detecting circuit 110 includes a comparator 112 and a flip flop 114. The comparator 112 includes a first terminal, a second terminal, and an output terminal. The first terminal and the second terminal of the comparator 112 are respectively used to receive the voltage signal VDDQ and a reference signal VTHX. The output terminal of the comparator 112 is used to output a comparison result as the detecting result. For example, when the level of the voltage signal VDDQ is greater than the level of the reference signal VTHX, the comparator 112 outputs the detecting result with a bit value of 1. When the level of the voltage signal VDDQ is less than or equal to the level of the reference signal VTHX, the comparator 112 outputs the detecting result with a bit value of 0.

Next, the flip flop 114 includes a first input terminal D, a second input terminal CK, and an output terminal Q. The first input terminal D of the flip flop 114 is used for receiving the bit value output by the comparator 112. The output terminal Q of the flip flop 114 is used to output a setting signal S1. The second input terminal CK of the flip flop 114 is used to receive a clock signal S2. When the clock signal S2 changes from 0 (a first bit value) to 1 (a second bit value), an output value of the flip flop 114 is equal to an input value.

The setting signal S1 output by the voltage detecting circuit 110 may be used to set the operating voltage range of the I/O buffer circuit 120. The operating voltage range of the I/O buffer circuit 120 may correspond to at least two different operating voltage ranges. Specifically, in an embodiment, the voltage signal VDDQ is, for example, 1.1 volt (V), and the reference signal VTHX is, for example, 0.85V. When the voltage detecting circuit 110 detects that the level of the voltage signal VDDQ is greater than the level of the reference signal VTHX, the voltage detecting circuit 110 outputs, for example, the setting signal S1 with the bit value of 1, and sets the I/O buffer circuit 120 in a first operating voltage range, for example, between 1.06V and 1.17V, according to the setting signal S1.

In addition, in another embodiment, the voltage signal VDDQ is, for example, 0.6V, and the reference signal VTHX is also 0.85V. When the voltage detecting circuit 110 detects that the level of the voltage signal VDDQ is less than or equal to the level of the reference signal VTHX, the voltage detecting circuit 110 outputs, for example, the setting signal S1 with the bit value of 0, and sets the I/O buffer circuit 120 is in a second operating voltage range, for example, between 0.57V-0.65V, according to the setting signal S1. The maximum value 0.65V of the second operating voltage range of 0.57V-0.65V is smaller than the minimum value 1.06V of the first operating voltage range of 1.06V-1.17V.

In this embodiment, the various values of the voltage signal VDDQ, the reference signal VTHX, the first operating voltage range, and the second operating voltage range are used for exemplary illustration and are in no way limiting.

In response to different levels of the voltage signal VDDQ, the mode setting of the mode register circuit 130 is also adjusted accordingly. The mode register circuit 130 may store at least two different mode settings. For example, the mode setting of the mode register circuit 130 may include setting values of various signals DS, ODT, and VREF required for the operation of the memory device 100, and the setting values of the signals DS, ODT, and VREF correspond to different levels of the voltage signals. For example, when the level of the voltage signal VDDQ is greater than the level of the reference signal VTHX, the signals DS, ODT, and VRE have a set of setting values corresponding to the voltage signal of 1.1V. When the level of the voltage signal VDDQ is less than or equal to the level of the reference signal VTHX, the signals DS, ODT, and VREF have another set of setting values corresponding to the voltage signal of 0.6V. Therefore, the mode setting of the mode register circuit 130 is adjusted along with different levels of the voltage signal VDDQ.

In addition, enough teaching, suggestion, and implementation illustration for the circuit structure and implementation manner of the I/O buffer circuit 120 and the mode register circuit 130 in the embodiment of the disclosure may be obtained from the common knowledge in the technical field.

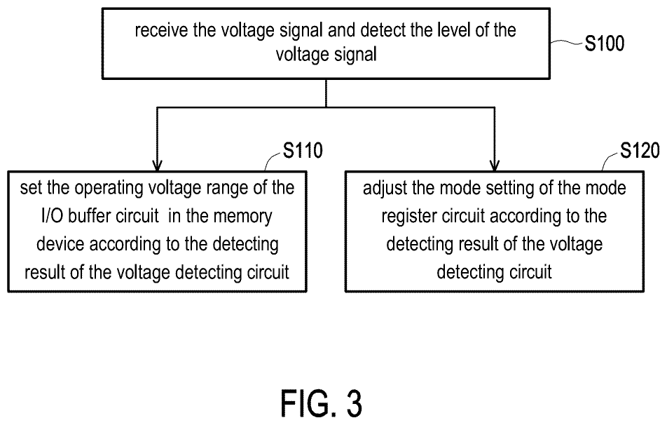

Referring to FIG. 1 and FIG. 3, an operating method of the memory device of this embodiment is at least suitable for the memory device 100 of FIG. 1, but the disclosure is not limited thereto.

Taking the memory device 100 as an example, in step S100, the voltage detecting circuit 110 receives the voltage signal VDDQ and detects the level of the voltage signal VDDQ. Next, in step S110, the operating voltage range of the I/O buffer circuit 120 in the memory device 100 is set according to the detecting result of the voltage detecting circuit 110. Alternatively, in step S120, the mode setting of the mode register circuit 130 is adjusted according to the detecting result of the voltage detecting circuit 110. In this embodiment, the steps S110 and S120 may be executed either one or both, and the steps S110 and S120 may be executed in no particular order or at the same time.

In addition, enough teaching, suggestion, and implementation illustration for the operating method of the memory device according to the embodiment of the disclosure may be obtained from the description of the embodiment in FIG. 1, which is not repeated herein.

In summary, in the embodiments of the disclosure, the memory device detects the level of the input voltage signal through the voltage detecting circuit, and sets the operating voltage range of the I/O buffer circuit or adjusts the mode setting of the mode register circuit accordingly. The input-output buffer circuit and the mode register circuit may be set or adjusted based on the detecting results. Therefore, a single memory device may support the levels of the voltage signals of different power inputs, giving manufacturers more flexibility in production, inventory, material preparation, cost control, and application design.

Although the disclosure has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A memory device, comprising:
a voltage detecting circuit, configured to receive a voltage signal and detect a level of the voltage signal; and
an input-output buffer circuit, disposed in the memory device, and coupled to the voltage detecting circuit, wherein based on a detecting result of the voltage detecting circuit, an operating voltage range of the input-output buffer circuit is set, and the operating voltage range of the input-output buffer circuit corresponds to at least two different operating voltage ranges.

2. The memory device according to claim 1, wherein
in response to a level of the voltage signal being greater than a level of a reference signal, the input-output buffer circuit is set in a first operating voltage range; and
in response to a level of the voltage signal being less than or equal to a level of the reference signal, the input-output buffer circuit is set in a second operating voltage range.

3. The memory device according to claim 2, wherein a maximum value of the second operating voltage range is smaller than a minimum value of the first operating voltage range.

4. The memory device according to claim 1, further comprising:
a mode register circuit, coupled to the voltage detecting circuit and configured to store at least two different mode settings.

5. The memory device according to claim 4, wherein the mode setting comprises setting values of a plurality of signals required for operation of the memory device, and the setting values of the plurality of signals correspond to different levels of the voltage signal.

6. The memory device according to claim 1, wherein the voltage detecting circuit comprising:
a comparator, comprising a first terminal, a second terminal, and an output terminal, wherein the first terminal of the comparator is configured to receive the voltage signal, the second terminal of the comparator is configured to receive a reference signal, and the output terminal of the comparator is configured to output a comparison result as the detecting result; and
a flip flop, comprising a first input terminal, a second input terminal, and an output terminal, wherein the first input terminal of the flip flop is configured to receive the detecting result, the second input terminal of the flip flop is configured to receive a clock signal, wherein in response to the clock signal changing from a first bit value to a second bit value, an output value of the flip flop is equal to an input value.

7. An operating method of a memory device, comprising:
receiving a voltage signal and detecting a level of the voltage signal; and
setting an operating voltage range of an input-output buffer circuit in the memory device according to a detecting result, wherein the operating voltage range of the input-output buffer circuit corresponds to at least two different operating voltage ranges.

8. The operating method of the memory device according to claim 7, wherein setting the operating voltage range of the input-output buffer circuit in the memory device according to the detecting result comprises:
in response to a level of the voltage signal being greater than a level of a reference signal, the input-output buffer circuit is set in a first operating voltage range; and
in response to a level of the voltage signal being less than or equal to a level of the reference signal, the input-output buffer circuit is set in a second operating voltage range.

9. The operating method of the memory device according to claim 8, wherein a maximum value of the second operating voltage range is smaller than a minimum value of the first operating voltage range.

10. The operating method of the memory device according to claim 7, further comprising:
storing at least two different mode settings in a mode register circuit of the memory device.

11. The operating method of the memory device according to claim 10, wherein the mode setting comprises setting values of a plurality of signals of the memory device, and the setting values of the plurality of signals correspond to different levels of the voltage signal.
